(19) United States
(12) Patent Application Publication
(10) Pub. No.: US 2009/0160056 A1
(43) Pub. Date: Jun. 25, 2009

(54) SEMICONDUCTOR DEVICE AND METHOD FOR MANUFACTURING THE SAME

(76) Inventor: Kweng-Rae Cho, Gumi-si (KR)

Correspondence Address: SHERR & VAUGHN, PLLC, 620 HERNDON PARKWAY, SUITE 200, HERNDON, VA, 20170, US

(21) Appl. No.: 12/127,027

(22) Filed: May 27, 2008

(30) Foreign Application Priority Data
Dec. 24, 2007 (KR) 10-2007-0136469

(51) Int. Cl. H01L 21/768; H01L 23/532

(52) U.S. Cl. 257/751; 438/653; 257/E21.585; 257/E23.155

(57) ABSTRACT

A semiconductor device and a method for manufacturing the same. The method can include forming a plurality of vias in a first interlayer insulation layer formed on a semiconductor substrate; and then forming a photoresist pattern over the first interlayer insulation layer to expose a portion of the first interlayer insulation layer and expose each via; and then forming a trench around an upper portion of each via by etching the exposed first interlayer insulation layer using the photoresist pattern as an etching mask; and then forming a metal layer over the first interlayer insulation layer including each trench; and then forming a plurality of metal lines over the vias and each trench by patterning the metal layer; and then forming a second interlayer insulation layer over the metal lines. Therefore, void generation between the metal lines during the highly integrated aluminum wiring process can be prevented.

The present application claims priority under 35 U.S.C. 119 to Korean Patent Application No. 10-2007-0136469 (filed on Dec. 24, 2007), which is hereby incorporated by reference in its entirety.

### BACKGROUND

Aspects of semiconductor technology have focused on achieving highly integrated semiconductor devices having high performance. This may be obtained by reducing metal line width of lines width.

Aluminum (Al) wiring process is one common process in the manufacturing of semiconductor devices. Application of such an aluminum wiring process may be used to obtain a fine pattern formation of 130 μm or less can be difficult since the aluminum wiring process is presently applied to a fine pattern formation of 65 μm. Moreover, in the aluminum wiring process, the most dense metal layer in the wiring may be a first metal layer formed closest to a semiconductor substrate. After forming the first metal layer, a high aspect ratio in a space between the wirings may be obtained by performing a process for depositing an interlayer insulator between the metal wirings. This process, however, increases the possibilities of forming voids between the metal wirings.

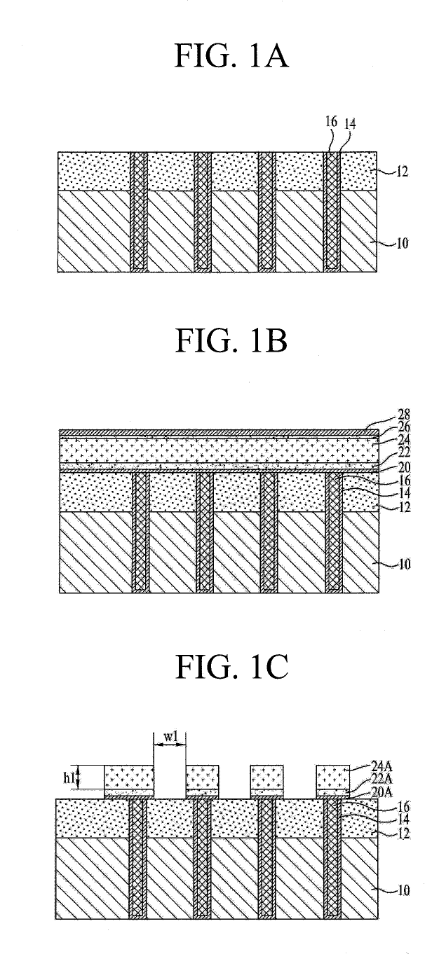

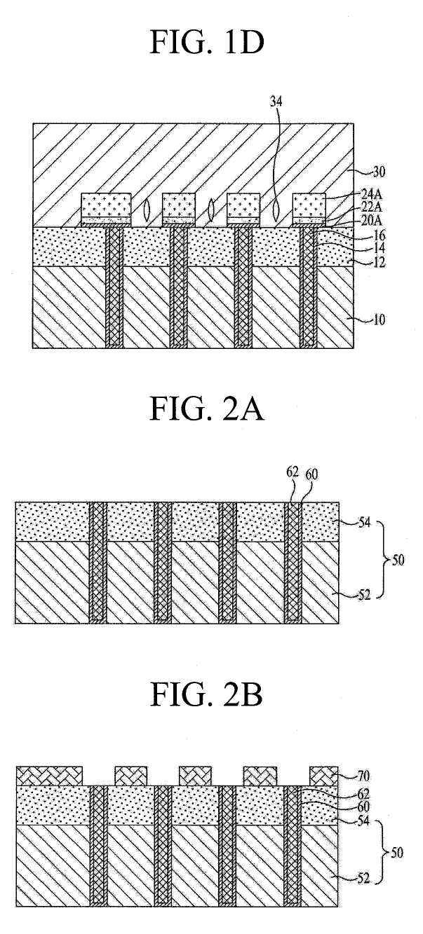

As illustrated in example FIGS. 1A-1D, a method for manufacturing a semiconductor device having a metal line will be described.

As illustrated in example FIG. 1A, a plurality of vias 16 penetrating first interlayer insulation layer 10 and second interlayer insulation layer 12 may be formed. Barrier layer 14 may then be formed in each via 16 and first interlayer insulation layer 10 and second interlayer insulation layer 12.

As illustrated in example FIG. 1B, second barrier layer 20, third barrier layer 22, aluminum layer 24, fourth barrier layer 26 and fifth barrier layer 28 may be sequentially laminated over vias 16, first interlayer insulation layer 10 and second interlayer insulation layer 12.

As illustrated in example FIG. 1C, a plurality of aluminum lines 24A may then be formed by patterning aluminum layer 24. Patterned barrier layers 20A and 22A remain between aluminum lines 24A and vias 16.

As illustrated in example FIG. 1D, a third interlayer insulation layer 30 may be formed over the entire surface of metal lines 24A and second interlayer insulation layer 12.

Manufacturing a semiconductor device in accordance with the above-described method, however, generates voids 34 in third interlayer insulation layer 30 and between metal lines 24 when the space between metal lines is too narrow. Such voids 34 may serve to deteriorate the insulation property of third interlayer insulation layer 30, as well as disconnect the lines in subsequent processes. This, in turn, may reduce the reliability of the semiconductor device.

Moreover, the insulation material, such as tetraethyl orthosilicate (TEOS), high density plasma (HDP)-undoped silicate glass (USG) or boron phosphorus silicate glass (BPSG), for filling the space between metal lines 24A may have a different step coverage due to a difference in the deposition method. This may cause more problems in the overall semiconductor device performance. Chemical vapor deposition (CVD) equipment may be used as the metal line width and the distance between the metal lines are narrowed. However, such equipment is very expensive, and thus, may increase the overall costs of the manufacturing process.

### SUMMARY

Accordingly, embodiments relate a semiconductor device and a method for manufacturing the same that prevents void generation between metal lines. This can be achieved, among other ways, by filling the metal layer in the trenches to form metal lines allowing a height of the metal lines to be reduced as much as the level difference of the trenches. Thus, there is a same effect of relatively enlarging the space between the metal lines. Meaning, since an aspect ratio between metal lines is reduced, void generation between the metal lines during the highly integrated aluminum wiring process can be prevented using interlayer insulation layer deposition equipment with a typical low performance, and without depending on the highly expensive CVD equipment. In turn, there is an effect of preventing defects in the resultant semiconductor device.

Embodiments relate to a method for manufacturing a semiconductor device that can include at least one of the following steps: forming a plurality of vias in a first interlayer insulation layer formed on a semiconductor substrate; and then forming a photoresist pattern over the first interlayer insulation layer to expose a portion of the first interlayer insulation layer and expose each via; and then forming a trench around an upper portion of each via by etching the exposed first interlayer insulation layer using the photoresist pattern as an etching mask; and then forming a metal layer over the first interlayer insulation layer including each trench; and then forming a plurality of metal lines over the vias and each trench by patterning the metal layer; and then forming a second interlayer insulation layer over the metal lines.

Embodiments relate to a method for manufacturing a semiconductor device that can include at least one of the following steps: forming a first interlayer insulation layer on a semiconductor substrate; and then forming a plurality of via holes in the first interlayer insulation layer; and then forming a plurality of vias by sequentially forming a first metal layer and a second metal layer in each via hole; and then forming a trench adjacent upper sidewalls of each via; and then sequentially forming a third metal layer and a fourth layer in the trenches and over the first interlayer insulation layer; and then forming a fifth metal layer in the trench and over the vias and each trench including the fourth metal layer; and then forming a plurality of metal lines over the vias and each trench by patterning the third metal, the fourth metal layer and the fifth metal layer.

Embodiments relate to a semiconductor device that can include at least one of the following: a first interlayer insulation layer formed over a semiconductor substrate; a plurality of vias extending through the first interlayer insulation layer; a metal line formed over the upper surface and sidewalls of each via; and a second interlayer insulation layer formed over the metal lines and the first interlayer insulation layer.

### DRAWINGS

Example FIGS. 1A to 1D illustrate a method for manufacturing a semiconductor device.

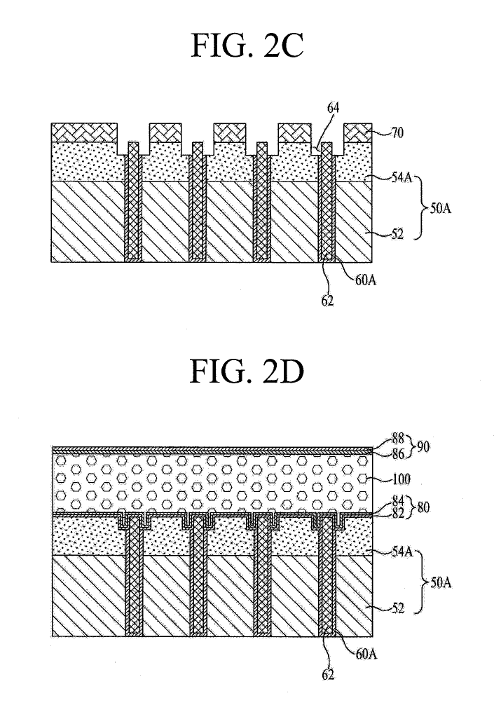

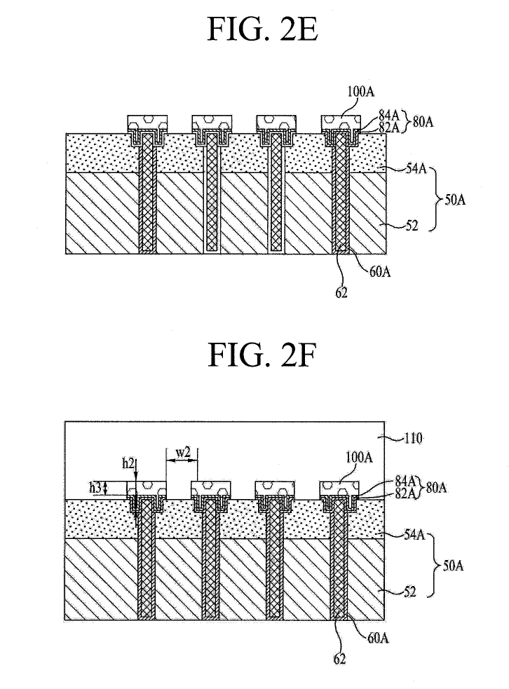

Example FIGS. 2A to 2F illustrate a method for manufacturing a semiconductor device, in accordance with embodiments.

### DESCRIPTION

As illustrated in example FIG. 2A, a plurality of vias 62 penetrating first interlayer insulation layer 50 formed directly on and/or over a semiconductor substrate can be formed. First interlayer insulation layer 50 may be formed directly on and/or over another interlayer insulation layer, instead of the semiconductor substrate. First interlayer insulating layer 50 may be composed of having a multilayer structure. For example, BPSG layer 52 may be formed on and/or over the semiconductor substrate, and oxide layer 54 can then be formed on and/or over the entire surface of BPSG layer 52 using SiH₄ gas. Accordingly, Meaning, first interlayer insulation layer 50 may include BPSG layer 52 and oxide layer 54.

A plurality of via holes can then be formed in first interlayer insulation layer 50. A metal material such as tungsten (W) can then be filled in the via holes to form vias 62. Barrier layer 60 may be formed in via 62 and extending through first interlayer insulation layer 50. Barrier layer 60 may be composed of TiN.

As illustrated in example FIG. 2B, a photoresist may be coated on and/or over the entire surface of oxide layer 54 of first interlayer insulation layer 50. A plurality of photoresist patterns 70 can then be formed on and/or over oxide layer 54 of first interlayer insulation layer 50 by a photograph and etching process to partially expose oxide layer 54 and expose vias 62.

As illustrated in example FIG. 2C, a plurality of trenches 64 can then be formed around (e.g., on both lateral sides) each via 62 by etching, e.g., using reactive ion etching (RIE), the exposed oxide layer 54 and barrier layer 60 using photoresist pattern 70 as an etching mask. In accordance with embodiments, the etching process for forming trenches 64 can be carried out by a light etching. Trenches 64 formed by the light etching can have a depth of between 100 to 500 Å. After forming trenches 64, photoresist pattern 70 can then be removed by performing an ashing process.

As illustrated in example FIG. 2D, metal layer 100 can then be formed over the entire surface of oxide layer 54A including trenches 64. Metal layer 100 may be composed of aluminum (Al). In accordance with embodiments, a first metal layer such as TiN layer 82 can be formed on and/or over oxide layer 54A, a second metal layer such as Ti layer 84 can then be formed on and/or over TiN layer 82, and then third metal layer 100 can then be formed on and/or over Ti layer 84. Accordingly, second barrier layer 80 composed of TiN layer 82 and Ti layer 84 can be formed. Third barrier layer 90 including Ti layer 86 and TiN layer 88 can then be formed on and/or over third metal layer 100 to prevent light reflection in the photograph and etching process for subsequently patterning metal layer 100.

As illustrated in example FIG. 2E, a plurality of metal lines 100A can then be formed by patterning metal layer 100 using a photograph and etching process. When patterning metal layer 100, second barrier layer 80 and third barrier layer 90 can be patterned together with metal layer 100. Therefore, second barrier layer 80A remains under each metal line 100A.

As illustrated in FIG. 2F, second interlayer insulation layer 110 can then be formed on and/or over metal lines 100A. Second interlayer insulation layer 110 can be composed of at least one of TEOS, HDP-USG, or BPSG and formed using chemical vapor deposition (CVD).

In accordance with embodiments, at least one pattern including first interlayer insulation layer 50A, via 62, metal line 100A, and second interlayer insulation layer 110 can be laminated vertically. In this case, a plurality of via holes can be formed in second interlayer insulation layer 110, and a metal such as tungsten (W) can then be filled in the via holes to form a plurality of new vias. Then, a plurality of metal lines can be formed over the new vias in accordance with the process illustrated in example FIGS. 2B to 2E.

Hereinbelow, according to an embodiment of the present invention will be described with reference to the accompanying FIG. 2f.

In accordance with embodiments, a semiconductor device can be formed including first interlayer insulation layer 50A including BPSG layer 52 and oxide layer 54A can be formed over a semiconductor substrate or another interlayer insulation layer. A plurality of vias 62 penetrating first interlayer insulation layer 50A can be formed and barrier rib 60A can then be formed in each via 62 and extending through first interlayer insulation layer 50A.

Metal line 100A can then be formed over the side and upper surfaces of each via 62. Barrier layer 80A including TiN layer 82A and Ti layer 84A can be formed between metal line 100A and via 62. Second interlayer insulation layer 110 can be formed over the entire surface of metal lines 100A and first interlayer insulation layer 50A.

In accordance with embodiments, at least one pattern including first interlayer insulation layer 50A, via 62, metal line 100A, and second interlayer insulation layer 110 can be laminated vertically. A plurality of via holes can be formed in second interlayer insulation layer 110 for electrically connecting with metal lines 100A, and metal lines 100A can be formed over each new via.

An aspect ratio can be defined as a ratio of a height in the vertical direction with respect to a width in the horizontal direction. In this case, the aspect ratio (AR1) of the semiconductor device illustrated in example FIG. 1C is shown in the following equation 1.

AR1=h1/w1 [Equation 1]

In accordance with Equation 1, h1 is a height of metal line 24A, and w1 is a width between metal lines 24A.

The semiconductor device in accordance with embodiments has an aspect ratio (AR2) as shown in the following equation 2.

AR2=h3/w2 [Equation 2]

In accordance with Equation 2, h3 is a height of metal line 100A exposed above first interlayer insulation layer 50A as illustrated in example FIG. 2F, and w2 is a width between metal lines 100A.

When filling the metal layer 100 in trenches 64, height h2 of metal line 100A exposed above first interlayer insulation layer 50A is reduced to a height smaller than height h1. Therefore, assuming that w1 and w2 are approximately the same, it can be known from Equations 1 and 2 that aspect ratio (AR1) is lower than aspect ratio (AR2). When height h1 of metal line 24A illustrated in example FIG. 1C is equally realized as height h2 of metal line 100A illustrated in example FIG. 2F, it can be known that aspect ratio (AR2) is reduced without influencing height h2 of metal line 100A formed over via 62.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a semiconductor device comprising:
forming a plurality of vias in a first interlayer insulation layer formed on a semiconductor substrate; and then
forming a photoresist pattern over the first interlayer insulation layer to expose a portion of the first interlayer insulation layer and expose each via; and then
forming a trench around an upper portion of each via by etching the exposed first interlayer insulation layer using the photoresist pattern as an etching mask; and then
forming a metal layer over the first interlayer insulation layer including each trench; and then
forming a plurality of metal lines over the vias and each trench by patterning the metal layer; and then
forming a second interlayer insulation layer over the metal lines.

2. The method of claim 1, wherein forming the vias comprises:
forming the first interlayer insulation layer by sequentially depositing a BPSG layer and an oxide layer on the semiconductor substrate; and then
forming a plurality of via holes in the first interlayer insulation layer; and then
filling the via holes with tungsten.

3. The method of claim 1, wherein forming the vias comprises:
forming the first interlayer insulation layer by sequentially depositing a BPSG layer and an oxide layer on the semiconductor substrate; and then
forming a plurality of via holes in the first interlayer insulation layer; and then
depositing a barrier layer in each via hole; and then
filling the via holes with tungsten.

4. The method of claim 1, wherein the second interlayer insulation layer is formed by chemical vapor deposition (CVD).

5. The method of claim 4, wherein the second interlayer insulation layer is composed of at least one of TEOS, HDP-USG and BPSG.

6. The method of claim 1, wherein forming the trench comprises selectively etching the exposed first interlayer insulation layer using a reactive ion etching process.

7. The method of claim 6, wherein the trench has a depth of between 100 to 500 Å.

8. The method of claim 1, wherein the metal layer comprises depositing aluminum over the first interlayer insulation layer including the trenches.

9. The method of claim 8, further comprising sequentially forming a TiN layer and a Ti layer in the trenches and on the first interlayer insulation layer before depositing the aluminum.

10. The method of claim 1, wherein forming the metal layer comprises:
sequentially forming a TiN layer and a Ti layer in the trenches and on the first interlayer insulation layer; and then
filling an aluminum layer in the trenches and on the TiN layer and the Ti layer.

11. A semiconductor device comprising:
a first interlayer insulation layer formed over a semiconductor substrate;
a plurality of vias extending through the first interlayer insulation layer;
a metal line formed over the upper surface and sidewalls of each via; and
a second interlayer insulation layer formed over the metal lines and the first interlayer insulation layer.

12. The semiconductor device of claim 11, wherein the first interlayer insulation layer comprises:
a BPSG layer formed on the semiconductor substrate; and
an oxide layer formed over the BPSG layer.

13. The semiconductor device of claim 11, wherein at least one pattern comprising the first interlayer insulation layer, the vias, the metal lines and the second interlayer insulation layer is repeatedly laminated vertically.

14. The semiconductor device of claim 11, further comprising a barrier layer comprising a TiN layer and a Ti layer formed between each via and a respective metal line.

15. The semiconductor device of claim 11, wherein the metal line partially buried in the trench is formed over the side surface of the upper via in the first interlayer insulation layer.

16. The semiconductor device of claim 15, wherein the metal line is composed of aluminum.

17. The semiconductor device of claim 16, further comprising a TiN layer and a Ti layer formed inside the trench and on each via between the first interlayer insulation layer and the metal lines.

18. The semiconductor device of claim 15, wherein trench has a depth of 100 to 500 Å.

19. The semiconductor device of claim 11, wherein the second interlayer insulation layer is composed of at least one of TEOS, HDP-USG and BPSG.

20. A method comprising:
forming a first interlayer insulation layer on a semiconductor substrate; and then
forming a plurality of via holes in the first interlayer insulation layer; and then
forming a plurality of vias by sequentially forming a first metal layer and a second metal layer in each via hole; and then
forming a trench adjacent upper sidewalls of each via; and then
sequentially forming a third metal layer and a fourth layer in the trenches and over the first interlayer insulation layer; and then
forming a fifth metal layer in the trench and over the vias and each trench including the fourth metal layer; and then
forming a plurality of metal lines over the vias and each trench by patterning the third metal, the fourth metal layer and the fifth metal layer.
